(19) United States
(12) Patent Application Publication
(10) Pub. No.: US 2014/0264681 A1
(43) Pub. Date: Sep. 18, 2014

(54) POLARIZATION INSENSITIVE PHOTOCONDUCTIVE SWITCH

(71) Applicant: Joseph R. Demers, North Hollywood, CA (US)

(72) Inventor: Joseph R. Demers, North Hollywood, CA (US)

(21) Appl. No.: 13/827,939

(22) Filed: Mar. 14, 2013

(51) Int. Cl. H01L 31/02

(52) U.S. Cl. CPC H01L 31/02
USPC 257/431

(57) ABSTRACT

A photoconductive switch semiconductor device including a semiconductor substrate including a region functioning as a photoconductive switch; and a metallization layer disposed on the surface of the semiconductor substrate including a first component including a first terminal, and an inwardly spiraling first middle portion, and a first end portion, and a second component including a second terminal, and an inwardly spiraling second middle portion, and a second end portion, wherein the first component and the second component are electrically isolated.

### BACKGROUND

1. Field

The present disclosure relates to photoconductive switch semiconductor devices or photomixers, such devices having application in microwave, millimeter wave and submillimeter wave spectroscopy systems and components.

2. Description of the Related Art

Terahertz devices and systems generally employ electromagnetic energy between 300 GHz and 3 terahertz (3 THz), or wavelengths from 100 to 1000 microns (0.1 to 1.0 millimeters), which is also referred to as the submillimeter or far-infrared region of the electromagnetic spectrum.

One application of terahertz systems is THz spectroscopy. Terahertz spectroscopy may present many new instrumentation and measurement applications since certain compounds and objects can be identified and characterized by a frequency-dependent absorption, dispersion, and/or reflection of terahertz signals which pass through or are reflected from the compound or object.

The generation of terahertz radiation by photomixing is a method of generating quasi-optical signals using an optical-heterodyne converter or photomixer. Typical photomixer devices include low-temperature-grown (LTG) GaAs semiconductor devices, which have been used to generate coherent radiation at frequencies up to 5 THz. The spectroscopy system typically uses two single frequency tunable lasers, such as diode lasers, to generate two optical laser beams which are directed at the surface of the photomixer. By photoconductive mixing of the two beams in the semiconductor material, a terahertz difference frequency between the two optical laser frequencies is generated. The THz radiation is generated as a result of transient currents in the semiconductor material in response to the short laser pulse, typically in the order of hundreds of femtoseconds, as the photoconductive material is switched from an insulating to a conducting state. An antenna structure is typically provided on the surface of the semiconductor material for radiating the resultant THz radiation into free space.

In more particularity, a first laser generates radiation at a first frequency and a second laser generates radiation at a second frequency. The difference frequency, equal to the difference between the first and the second laser frequencies, is swept by the user from microwave through terahertz frequencies by changing the temperature of the lasers, which coarsely changes the frequency of one or both lasers. Other types of tuning mechanisms exist, such as distributed-Bragg-reflector diode lasers with multiple electrodes, grating-loaded external cavities, etc.

A terahertz spectroscopy system includes a terahertz transmitter and a terahertz receiver, with the receiver spaced apart from the transmitter and positioned with respect to the target so as to receive the reflected or transmitted terahertz ration from the target. The terahertz transmitter may include a first photomixer that is optically coupled to the first and the second light source. A first radiative element or antenna is electrically coupled to the first photomixer. In operation, the first antenna radiates a terahertz signal generated by the first photomixer at the difference frequency. A receiver includes a second antenna positioned to receive the signal from the target radiated by the first antenna. The second antenna generates a time varying voltage proportional to the terahertz return signal. A second photomixer is electrically coupled to the second antenna and is optically coupled to the first and the second light source. The second photomixer generates a homodyne downconverted current signal in response to the time varying voltage generated by the second antenna. The downconverted signal is a measurement of the absorption or reflection of the material at each terahertz frequency. This may be useful, for example, when used in conjunction with computer processing to identify unknown samples by comparing measured results to a library of reference spectra. This apparatus may also be used to characterize the frequency response characteristics of passive or active components and devices such as waveguides, filters, amplifiers, mixers, diodes, and the like designed to work at terahertz frequencies.

Historically photomixers employed for constant-wave (CW) microwave and THz generation have used an antenna structure that employs a fingered pattern in the optical mixing section in the center of the antenna to improve the optical response of the structure. The fingers may be designed to be as narrow as possible to increase the active area of the GaAs (e.g., the use of wider fingers means that more surface area of the semiconductor is covered thereby decreasing the amount of the semiconductor surface that is exposed to the laser beams). The gaps between the fingers are chosen to minimize the capacitance of the antenna. While the fingered section of the antenna improves the efficiency of the photomixer in CW operation, it imposes a polarization requirement on the optical radiation.

The present disclosure is directed to a photomixer or photoconductive switch with a new and improved antenna shape or structure.

### SUMMARY

### 1. Objects

It is an object of the present disclosure to provide an improved photoconductive switch or photomixer.

It is another object of the present disclosure to provide a polarization independent photoconductive switch.

### 2. Features

Briefly, and in general terms, the present disclosure provides a photoconductive switch semiconductor device including a semiconductor substrate including a region functioning as a photoconductive switch; a metallization layer disposed on the surface of the semiconductor substrate including a first component including a first terminal, and an inwardly spiraling first middle portion, and a first end portion, and a second component including a second terminal, and an inwardly spiraling second middle portion, and a second end portion, wherein the first component and the second component are electrically isolated; wherein the inwardly spiraling first middle portion and the inwardly spiraling second middle portion are interdigitated and each comprise an elongated trace of equal width, and wherein the first end portion and the second end portions are each comprised of at least first, second, third and fourth linear traces of equal width and successively shorter lengths and are inwardly spiraling.

In another aspect, the present disclosure may provide an apparatus for analyzing, identifying or imaging a target, including first and second lasers having tunable frequencies, the first laser to produce a first output beam and the second laser to produce a second output beam, the first output beam and the second output beam having different frequencies; and a photoconductive switch of the type described above utilized in connection with the first and second lasers.

In another aspect, the present disclosure provides that the photoconductive switch may be a low temperature grown GaAs photoconductive switch.

In another aspect, the present disclosure provides first and second thermoelectric coolers that may be coupled to the first and second lasers, respectively, for independently coarsely tuning each of the lasers over a wavelength range of about 5 nm in intervals or step sizes of about 0.01 nm.

In another aspect, the present disclosure provides the first and second lasers may be distributed feedback (DFB) or distributed Bragg reflector (DBR) semiconductor lasers tuned to different frequencies.

In another aspect, the present disclosure provides the first and second lasers may be external cavity lasers.

In another aspect, the present disclosure provides the photoconductive switch may be biased with a constant electrical potential.

Some implementations or embodiments may incorporate or implement fewer of the aspects or features noted in the foregoing summaries.

Additional objects, advantages, and novel features of the present invention will become apparent to those skilled in the art from this disclosure, including the following detailed description as well as by practice of the invention. While the invention is described below with reference to preferred embodiments, it should be understood that the invention is not limited thereto. Those of ordinary skill in the art having access to the teachings herein will recognize additional applications modifications and embodiments in other fields, which are within the scope of the invention as disclosed and claimed herein and with respect to which the invention could be of utility.

### BRIEF DESCRIPTION OF THE DRAWINGS

These and other features and advantages of this invention will be better understood and more fully appreciated by reference to the following detailed description when considered in conjunction with the accompanying drawings wherein:

FIG. 1 is a top view of a first photoconductive switch known in the prior art; and

FIG. 2 is a top view of a photoconductive switch according to the present disclosure.

The novel features and characteristics of the disclosure are set forth in the appended claims.

### DETAILED DESCRIPTION OF THE PREFERRED EMBODIMENT

Details of the present disclosure will now be described, including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of actual embodiments or the relative dimensions of the depicted elements, and are not drawn to scale.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

FIG. 1 is a top view of a first is a top view of a photoconductive switch 100 known in the prior art. The photoconductor switch, or semiconductor device, 100 is typically formed from a low-temperature-grown (LTG) GaAs semiconductor substrate, although other semiconductors may be used. On the surface of the semiconductor is a metallization pattern, typically of gold, forming an antenna for the transmission and/or reception of THz signals. On opposite sides of the top surface of the semiconductor surface are terminals 201 and 202. The antenna in some embodiments is implemented as the spiral in the central region as shown, with the gap located at the center of the spiral depicted in the enlarged region in the right hand portion of the FIG. 1. The enlarged region depicts the metallization traces 203 and 204 converging in a gap 205, in which fingers 206, 207 and 208 are electrically connected to metallization trace 204, and fingers 209, 210 and 211 are electrically connected to metallization trace 203.

Historically photo-mixers employed for constant-wave (CW) microwave and THz generation have employed an antenna structure that employs a fingered pattern in the optical mixing section in the center of the spiral. The gaps between the fingers are chosen to minimize the capacitance of the antenna. While the fingered section of the antenna may improve the efficiency of the photomixer in CW operation, the section may impose a polarization requirement on the optical radiation antenna to improve the optical response of the structure. The fingers may also be designed to be as narrow as possible to increase the active area of the GaAs. The most efficient conversion of the optical radiation into THz radiation occurs when the optical electric field is perpendicular to the finger structure, i.e., orthogonal to the fingers 206, 207, 211, etc. as shown in the antenna design of FIG. 1, which may align the optical field with the direction of bias as applied to the terminals 201 and 202. Aligning the electric field parallel to the finger structure will may result in a 3 dB decrease in the conversion efficiency. In a system comprised of a photomixer as a source and as a detector, this could result in a system signal to noise ratio decrease of twice that, or 6 dB.

FIG. 2 is a top view of a photoconductive switch 300 according to the present disclosure. The photoconductive switch 300 is semiconductor device that may be formed from a low-temperature-grown (LTG) GaAs semiconductor substrate, although other semiconductors may be used. On the surface of the semiconductor substrate is a metallization pattern, typically of gold, forming an antenna for the transmission and/or reception of THz signals. On opposite sides, or end regions, of the top surface of the semiconductor surface are terminals 301 and 302. The antenna in some embodiments may be implemented as the spiral in the central region as shown with the gap, or gap region, located at the center of the spiral depicted in the enlarged region of FIG. 1. The enlarged region depicts the metallization trace 303 and 304 converging in a gap, or gap region, in which fingers 306, 307, 308 and 309 are serially connected and electrically connected to metallization trace 304, and fingers 310, 311, 312 and 313 are serially connected and electrically connected to metallization trace 305. Such as design may be polarization insensitive. In other words, such a design may not be sensitive to the orientation of the electric field.

The polarization insensitive aspect of the present design compared to the straight finger design of the prior art shown in FIG. 1 may be understood as follows. Consider different optical E fields represented by a vector superimposed on the spiral in spiral antenna. In either case, a field parallel to a finger 306, or the case of an orthogonal field, parallel to finger 307, the field is perpendicular to some part of the inner spiral's arms such as, e.g., fingers 306, 307, 308, etc). On the other hand, if one superimposes the same electric field on the straight fingered devices of FIG. 1, one will note that, in one case, the E field is perpendicular to the fingers (which, e.g., may provide a good effect), and in the other case, the E field is parallel to the fingers (which, e.g., may be provide a bad effect).

An exemplary being used in a spectroscopy system using the exemplary photoconductive switch 300 system may typically uses two single frequency tunable lasers, such as diode lasers, to generate two optical laser beams which are directed at the surface of the photomixer. Laser subassemblies may include lasers that are preferably two 783 nm distributed feedback (DFB) or distributed Bragg reflector (DBR) semiconductor laser diodes with single-longitudinal-mode and single spatial-mode operation over the desired range of wavelengths, available from various vendors such as, e.g., Eagleyard Photonics GmbH of Berlin, Germany, or Photodigm, Inc. of Richardson, Tex. In some embodiments, it would also be possible to utilize one or more packaged external-cavity tunable semiconductor lasers such as are available from Emcore Corporation, of Newark, Calif., such as disclosed in U.S. patent application Ser. No. 12/722,825, filed Mar. 12, 2010. In one embodiment, the output of one laser may be adjusted to 783 nm, and the output of the other laser may be adjusted to 784 nm. The diode laser packaging may permit co-collimation of the laser beams to a very high degree of precision, and the design may also allow a very precise frequency control of the lasers by temperature and/or electronic tuning and monitoring the laser output through digital signal processing to achieve more accurate control over the laser output beam frequencies.

In one embodiment, the laser diode chips are mounted on independent Peltier thermoelectric coolers (TECs). The center wavelengths of the lasers may be nominally 783 nm at 25° C., but the wavelengths may be coarsely temperature-tuned with a tuning coefficient of approximately 0.1 nm per ° C. Therefore, a 50 degree C. temperature range of operation from −10 degrees C. to +40 degrees C. may yield a frequency range of approximately 5 nm. For the purposes of illustration only, if the DFB lasers are selected such that their center wavelengths at 25 degrees C. are at 782 nm and 784 nm, respectively, then a thermal tuning range of −10 degrees C. to +40 degrees C. on each laser chip will permit generation of offset wavelengths 0 nm to approximately 7 nm, corresponding to a range of offset frequencies from 0 Hz to 3.4 THz. The thermal mass on the controlled surface of the TECs may be such that it allows rapid frequency tuning. In the case of DBR laser diode chips, the Bragg-reflection section of each laser may be adjusted electronically to vary the laser frequency. Wider offset frequency ranges may also be possible by employing wider temperature excursion, or by using DBR or external cavity lasers.

The output beam from each laser is collimated with an aspheric lens respectively, mounted on a precision lens-mount with sub-micron adjustment capability (see, e.g. U.S. Pat. No. 7,126,078). After passing through the lens, the laser output beams may be directed through a respective optical isolator, to prevent feedback into the laser, and to couple the output beam to pigtail optical fibers, respectively.

In a THz system source head, the composite output beam of the two distinct laser sources is then applied to a lens which focuses the beam to a spot of approximately ten microns in diameter on the surface of a low temperature grown (LTG) gallium arsenide (GaAs) photoconductive switch (PCS). The two optical beams may be combined or photomixed in the PCS. Other types of photoconductive switches may be used as well. The laser beam may be focused at a gap in an antenna circuit patterned on the surface of the PCS, with the gap located at the center of the spiral. A constant DC electrical bias coupled to the source head by cable may also be applied across the terminals of the antenna on the PCS. In some embodiments, a slowly time-varying, or “chopped,” electrical bias signal may be applied across the terminals of the antenna on the PCS.

The terahertz variation in the intensity of the mixing or difference signal between the two laser frequencies, often referred to as the “heterodyne laser signal,” may produce a terahertz modulation of the conductance in the PCS material, which in turn produces a terahertz current flow in the antenna patterned on the surface of the PCS. This current in the antenna may produce an electromagnetic field, e.g., terahertz radiation, propagating into the surrounding space and having a frequency range from typically 100 GHz to over 2 THz, depending on the difference frequency of the two laser sources. The terahertz radiation so produced may be emitted from PCS device and then collimated and collected by a silicon lens, preferably a hemispherically shaped structure approximately two to three centimeters in diameter. Additional lenses, composed of TEFLON™ or other suitable materials, may be placed downstream of the lens to collimate the RF beams into an output terahertz beam. Beam-shaping mirrors may also be used in lieu of or in addition to the silicon lens in the source head.

In summary, certain aspects of the present disclosure may provide a compact frequency domain terahertz coherent spectrometer with either continuous tuning, or discrete tuning within certain identified frequency bands greater than 100 GHz. Such construction may employ highly compact photonic integration techniques, and room-temperature coherent THz detection. Advantageously, such devices may offer rapid identification of chemical, biological and explosive materials in both the solid-phase and the gas-phase at standard atmospheric pressure. Some embodiments may utilize a highly integrated photonic assembly employing semiconductor diode lasers employing no moving parts, so that it is inherently rugged and well-suited to field-deployable applications. The frequency-shifted optical beams are incident on the source PCS (or alternatively, in other embodiments, the detector PCS, or both) and may provide a means to effect extremely high-resolution spectroscopy. Further, one may adjust the frequency of the source optical heterodyne signal with finer resolution than is typically possible using thermal control of the lasers alone. Typical thermal tuning resolution and accuracy of the source lasers may perform coarse tuning over a wavelength range up to 15 nm, in intervals or step sizes of about 0.01 nm.

Of course, various modifications and improvements of the present disclosure may also be apparent to those of ordinary skill in the art. Thus, the particular combination of parts described and illustrated herein is intended to represent only certain embodiments of the present invention, and is not intended to serve as limitations of alternate devices within the spirit and scope of the invention.

It will be understood that each of the elements described above, or two or more together, also may find a useful application in other types of constructions differing from the types described above. In particular, certain configurations presented according to particular aspects of the present invention have been shown and described as discrete elements, i.e., lasers, splitters, combiners, mirrors, lenses, shifters, fiber optical cable, etc. Those skilled in the art will readily appreciate that many or all of these individual, discrete components may be fabricated and/or packaged into integrated elements. By way of particular example, the use of integrated waveguides and associated structures is envisioned for the described structures and arrangements. Alternatively, the discrete elements, i.e., lasers, splitters, combiners, mirrors, lenses, shifters, etc. may also be individually-packaged in modules with optical fiber interconnects to achieve the same topology and functionality.

While the present disclosure illustrates and describes a terahertz transceiver or spectrometer system, it is not intended to be limited to the details shown, since various modifications and structural changes may be made without departing in any way from the spirit of the present invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The foregoing described embodiments depict different components contained within, or connected with, different other components. It is to be understood that such depicted arrangements or architectures are merely exemplary, and that in fact many other arrangements or architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of specific structures, architectures or intermedial components. Likewise, any two components so associated can also be viewed as being “operably connected” or “operably coupled” to each other to achieve the desired functionality.

While particular embodiments of the present invention have been shown and described, it will be understood by those skilled in the art that, based upon the teachings herein, changes and modifications may be made without departing from this invention and its broader aspects and, therefore, the appended claims are to encompass within their scope all such changes and modifications as are within the true spirit and scope of this invention. Furthermore, it is to be understood that the invention is solely defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” “comprise” and variations thereof, such as, “comprises” and “comprising” are to be construed in an open, inclusive sense, that is as “including, but not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Without further analysis, from the foregoing others can, by applying current knowledge, readily adapt the disclosed technology for various applications. Such adaptations should and are intended to be comprehended within the meaning and range of equivalence of the following claims.

What is claimed is:

1. A photoconductive switch semiconductor device comprising:
a semiconductor substrate including a region functioning as a photoconductive switch;
a metallization layer disposed on the surface of the semiconductor substrate including a first component including a first terminal, and an inwardly spiraling first middle portion, and a first end portion, and a second component including a second terminal, and an inwardly spiraling second middle portion, and a second end portion, wherein the first component and the second component are electrically isolated;
wherein the inwardly spiraling first middle portion and the inwardly spiraling second middle portion are interdigitated and each comprise an elongated trace of equal width, and
wherein the first end portion and the second end portions are each comprised of at least first, second, third and fourth linear traces of equal width and successively shorter lengths and are inwardly spiraling.

2. A device as defined in claim 1, wherein the semiconductor is a low temperature grown GaAs.

3. A device as defined in claim 1, wherein the metallization layer forms an antenna structure which is polarization insensitive.
